(19) United States
(12) Patent Application Publication
(10) Pub. No.: US 2004/0159929 A1
(43) Pub. Date: Aug. 19, 2004

(54) Semiconductor die package having two die paddles

(76) Inventors: Andreas Huschka, Dresden (DE); Wolfram Kluge, Dresden (DE); Uwe Hahn, Berbesdorf (DE)

Correspondence Address: B. Noel Kivlin, Meyertons, Hood, Kivlin, Kowert & Goetzel, P.C., P.O. Box 398, Austin, TX, 78767, US

(21) Appl. No.: 10/777,688

(22) Filed: Feb. 12, 2004

Related U.S. Application Data
(62) Division of application No. 10/185,148, filed on Jun. 27, 2002.

(30) Foreign Application Priority Data
Feb. 11, 2002 (DE) 102 05 563.7

(51) Int. Cl. H01L 23/02

(52) U.S. Cl. 257/678

(57) ABSTRACT

A package for packaging a semiconductor die is provided that increases the reliability of packaged semiconductor circuits in particular in high frequency applications where both analog and digital signals are used. The package comprises a first die attach paddle which is connectable to a first part of a bottom surface of the semiconductor die, and a second die attach paddle which is connectable to a second part of the bottom surface of the semiconductor die. The first and second die attach paddles are each made of an electrically conductive material, and are electrically separated from each other. Further, a corresponding semiconductor device and a method of fabricating a package and packaging a semiconductor die are provided. When packaging dies having analog and digital circuits, separate grounds not only on the chip but also in the package can be achieved so that cross talking problems can be effectively reduced.

### BACKGROUND OF THE INVENTION

1. Field of the Invention

The invention generally relates to packages for semiconductor devices such as integrated circuits and, more particularly, to packages for packaging a semiconductor die and providing electrical contacts to the packaged semiconductor die.

2. Description of the Related Art

Presently, several techniques have been developed for packaging semiconductor dies or chips. A number of different package designs is specified by Joint Electronic Devices Engineering Conference (JEDEC) standards including plastic or ceramic designs. An example of a JEDEC compliant package design is QFP (Quad Fiat Pack).

Semiconductor die packages take many forms, but in general they include a substrate which may include a shallow cavity for holding the semiconductor die. Further, the packages include either a metallised and plated lead pattern or a metallic lead frame having inner lead tips surrounding the cavity and leads extending out to the edge of the substrate. The leads are bent or formed in a suitable configuration for electrical connection into a socket, circuit board, printed wiring board, application board, etc.

An example of a package design that includes a lead frame is the above mentioned QFP package. Lead frames are so named because all the leads for a device are held together by an outer connecting frame. The frame surrounds a paddle to which the die is attached to fix the die. The paddle is located in the bottom of the cavity.

To reduce the parasitics generated through signal transmission from the die to the board via bond wires and/or the lead frame, a number of modified package designs have been developed in particular for high frequency applications.

One of these techniques is the BCC (Bump Chip Carrier) design where no lead frame is used. Another technique which is directed to the reduction of parasitic effects and which still uses a lead frame is the QFN (Quad Flat Non-Lead) technique where the lead frame is significantly reduced. QFN packages can be thought as being formed by removing the lower portion from QFP packages and cutting off the leads to trim the lead frames leaving terminals.

The QFN technique is illustrated in FIG. 1 which shows a cross-sectional view of a QFN package encapsulating a semiconductor die 100. The structure includes the die 100 and a number of leads 110 held together to form a lead frame. The die 100 comprises bonding pads which are electrically connected to respective leads 110 by the use of bonding wires 120. While the bonding pads of the die 100 are disposed on the upper surface of the die, i.e. the active surface, the die 100 further includes a back surface which may contain a ground contact. The die 100 has its back surface bonded to the die attach paddle 130 by the use of adhesive material 140. Lastly, the die 100, the leads 110, the die attach paddle 130, and the bonding wires 120 are encapsulated by a molding compound 150.

While such QFN packages are satisfactory in many applications it has been found that in particular for high frequency applications with high power consumption a problem arises because there is an insufficient terminal heat transfer from the die to the exterior. To overcome this problem, packages have been developed that have a direct wide area contact to the application board.

As can be seen from FIG. 1, the paddle 130 is vertically offset so that the die 100 and the leads 110 are positioned at different levels. A package having an exposed paddle is the MLF (MicroLeadFrame™) package which is a plastic encapsulated package with a copper lead frame substrate. This technique is illustrated in FIG. 2.

Like the QFN packages, the MLF package uses perimeter lands on the bottom of the package to provide electric contact to the application board. The MLF package also offers a thermal enhancement by having the die attached paddle 200 exposed on the bottom of the package surface to provide an efficient heat path when soldered directly to the application board. Thus, the paddle 200 is not vertically offset but is found at the same level as the leads 110. By use of a down bond 220 or by electrical connection through a conductive die attach material, the MLF package enables stable ground to improve the electrical performance by reducing interference. Further, there may be a ground bond 210 provided.

Turning now to FIG. 3, a standard paddle design that is usable in most lead frame based package designs is shown in a top view. As can be seen, the paddle is a (substantially) square or so-called “quad” or “chip carrier” package having forty-eight leads disposed at the edges of the square. Further, there is a substantially square paddle 130, 200 which is fixed on the corner of the lead frame using paddle leads 300.

While the above discussed techniques may often be satisfactory with respect to the reduction of parasitics and the thermal behaviour, the techniques are still disadvantageous when encapsulating semiconductor circuits that are used for high frequency applications such as RF (Radio Frequency) applications beyond 5 GHz, for instance in transceivers using frequencies in the 5.2 GHz or 5.8 GHz band. In particular, when using both analog and digital signals in one package device, there may occur cross talking which deteriorates the signal quality. This might lead to wrong circuit operations and can pose a severe problem in the normal operation as well as in the electrical characterisation of the circuit.

### SUMMARY OF THE INVENTION

An improved package for packaging a semiconductor die is provided that increases the reliability of packaged semiconductor circuits in particular in high frequency applications where both analog and digital signals are used. Further, a corresponding semiconductor device and a method of fabricating a package and packaging a semiconductor die are provided.

In one embodiment, a package for packaging a semiconductor die and providing electrical contacts to the packaged semiconductor die is provided that comprises a first die attach paddle which is connectable to a first part of a bottom surface of the semiconductor die. Further, the package comprises a second die attach paddle which is connectable to a second part of the bottom surface of the semiconductor die. The first and second die attach paddles are each made of an electrically conductive material, and are electrically separated from each other.

In another embodiment, a semiconductor device is provided that comprises a first die attach paddle which is made of an electrically conductive material. The semiconductor device further comprises a second die attach paddle which also is made of an electrically conductive material. At least one semiconductor die is comprised in the semiconductor device and has a bottom surface attached to the first and second die attach paddles. The first and second die attach paddles are electrically separated from each other.

In a further embodiment, a method of fabricating a package for packaging a semiconductor die and providing electrical contacts to the packaged semiconductor die is provided. The method comprises providing a first die attach paddle made of an electrically conductive material; providing a second die attach paddle made of an electrically conductive material; and placing the first and second die attach paddles so that the bottom surface of the semiconductor die can be attached to the first and second die attach paddles, and the first and second die attach paddles are electrically separated from each other.

In yet another embodiment, a method of packaging a semiconductor die is provided. The method comprises providing a package that has a first die attach paddle and a second die attach paddle which are made of an electrically conductive material and which are electrically separated from each other. The method further comprises providing the semiconductor die and attaching the bottom surface of the semiconductor die to the first and second die attach paddles.

### BRIEF DESCRIPTION OF THE DRAWINGS

The accompanying drawings are incorporated into and form a part of the specification for the purpose of explaining the principles of the invention. The drawings are not to be construed as limiting the invention to only the illustrated and described examples of how the invention can be made and used. Further features and advantages will become apparent from the following and more particular description of the invention, as illustrated in the accompanying drawings, wherein:

FIG. 1 is a cross sectional view of a conventional QFN package;

FIG. 2 is a cross sectional view of a MLF package;

FIG. 3 is a top view of a conventional lead frame based package;

FIG. 4 is a top view of a semiconductor die package according to a first embodiment; and

FIG. 5 is a top view of a semiconductor die package according to a second embodiment.

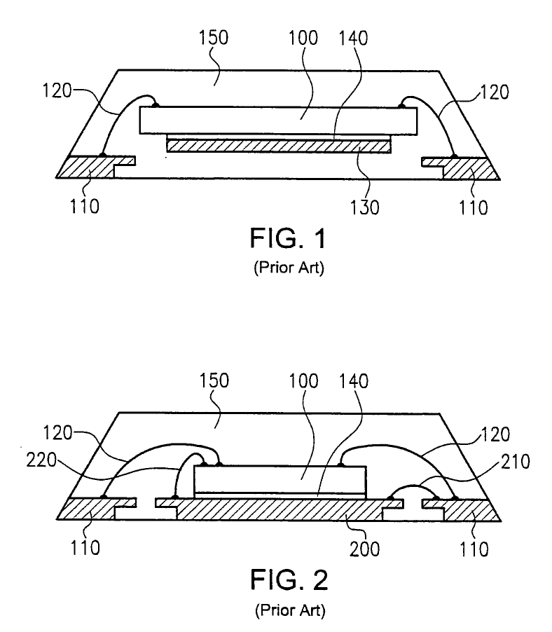

### DETAILED DESCRIPTION OF THE INVENTION

The illustrative embodiments of the present invention will be described with reference to the figure drawings wherein like elements and structures are indicated by like reference numbers.

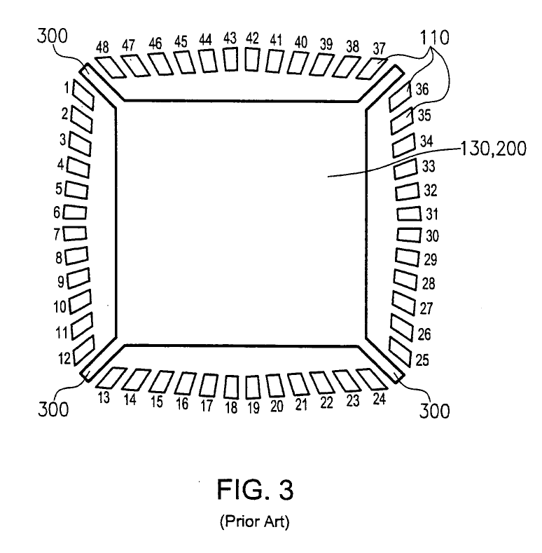

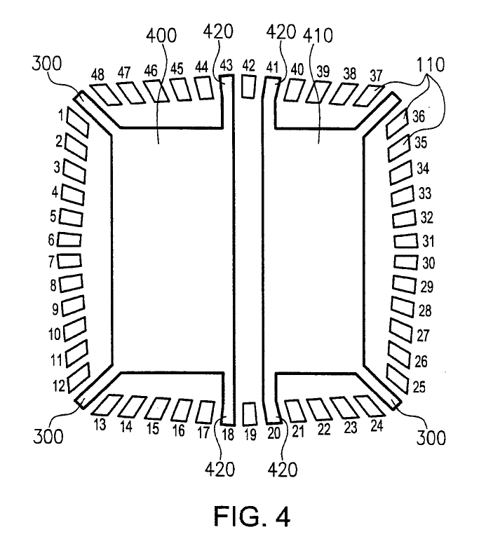

Referring now to the drawings and particularly to FIG. 4 which illustrates a first embodiment of the package, there is provided a lead frame containing forty-eight leads 110, like in the arrangement of FIG. 3. The lead frame has a substantially square shape, i.e. the package is a square or “quad” or “chip carrier” package. In other embodiments, rectangular frames and packages may be provided. Embodiments are further possible that provide lead frames and packages of arbitrary shape.

Within the area spanned by the leads 110, there are provided two die attach paddles 400, 410 in the embodiment of FIG. 4. The paddles 400, 410 have a substantially rectangular shape and are disposed adjacent each other. In the embodiment of FIG. 4, the distance between the two die attach paddles 400, 410 is greater than the width of one of the leads 110.

The paddles 400, 410 are fixed to the lead frame using standard paddle leads 300 at the corners of the lead frame, and common leads 420 near the center of a side of the lead frame. It is noted that in the present embodiment both paddles 400, 410 are fixed to the lead frame at four connection points 300, 420, thus establishing a secure mechanical connection.

The die attach paddles 400, 410 are exposed on the bottom surface of the package, much like in the MLF technique described above with reference to FIG. 2. That is, the paddles 400, 410 are not vertically offset with respect to the leads 110 but are located in the same level. It is however contemplated that in other embodiments the paddles 400, 410 may be vertically offset.

The die attach paddles 400, 410 are made of an electrically conductive material. When placing the semiconductor die onto the paddles 400, 410, the paddles 400, 410 provide separate grounds to the chip. For instance, the chip may comprise an analog and a digital circuit for generating or processing analog and digital signals, respectively. Such a chip may provide on its bottom surface two separate ground contacts, one for establishing an analog ground and the other one for establishing a digital ground. When packaging such chip using the package of FIG. 4, the analog and digital circuits have separate grounds not only on the chip but also in the package. Thus, there are separate grounds within the entire signal path from die to package, and in case of exposed paddles from the paddles to the application board.

In another configuration, the package of FIG. 4 may encapsulate two separate dies, one including analog circuitry and the other including digital circuitry. In this configuration, the die containing the analog circuitry may be placed on paddle 400 while the die containing the digital circuitry is placed on paddle 410. That is, in this arrangement the paddles 400, 410 are used to provide grounds not only to different circuits of the same die but even to different dies. As the paddles 400, 410 are electrically separated, each die may have its own signal path down to the application board.

In order to provide electrically separated die attached paddles 400, 410, the paddles may be provided as separate pieces of metallic or metallized substrate. In another embodiment, the paddles 400, 410 are made by metallization or plating of one and the same insulating substrate.

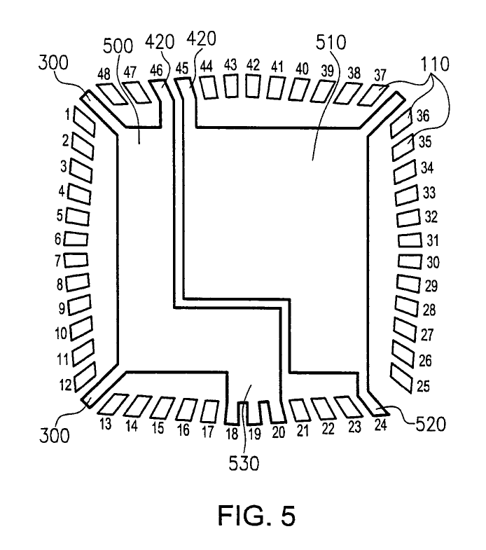

Turning now to FIG. 5, a second embodiment is shown that resembles most of the structures discussed with respect to FIG. 4. In the package of FIG. 5, there are two die attach paddles 500, 510 provided which are not of substantially rectangular shape. Rather, the paddles 500, 510 are designed to follow a given partitioning of the integrated circuit design of the semiconductor die which is to be packaged. That is, if the package is intended to encapsulate a chip that has analog and digital circuitry and where the analog circuitry is disposed at one side of the die in an, e.g., L shape, the paddles 500, 510 are shaped accordingly. If the die has at its bottom surface ground contacts of corresponding shapes, it can be placed into the cavity of the package to be attached onto paddles 500, 510 such that the L shaped ground contact of the analog circuitry fits onto paddle 500 while the other ground contact fits onto the L shaped paddle 510. In this example, paddle 500 would be used to provide ground to the analog circuits while paddle 510 provides the ground to the digital circuits.

Having regard to paddle 510, it is noted that the paddle has a three point connection to the lead frame. The paddle 510 is fixed to the lead frame using a paddle lead at the upper right corner, and using a lead 420 similar to the arrangement of FIG. 4. In addition, the paddle 510 is fixed to the lead frame using a customized corner connection 520 which is a common lead in the vicinity to a corner of the lead frame. In contrast thereto, the paddle 500 is fixed to the lead frame using more than three or four connection points. The paddle 500 is fixed to two paddle leads 300, one common lead 420 and three additional leads that form a multiple common lead 530.

When fabricating packages such as those of FIGS. 4 and 5, the two paddles 400, 410 or 500, 510 are first provided. As mentioned above, the two paddles can be embodied as one physical unit so that the provision of the paddles can be actually done in one method step. Then, the paddles are placed to form the bottom of the cavity so that the bottom surface of the die or the dies can later be attached to the paddles.

This “die attach” operation is done when packaging the semiconductor die, for securing the die or dies in the bottom of the cavity, e.g. using conductive adhesive material. Once the die is attached to the paddles, a “wire bond” operation is performed for connecting individual contact pads on the die with individual inner lead tips, generally using extremely fine gold or aluminium wire. Finally, the cavity is hermetically sealed using a molding compound and/or a cover.

The embodiments described above may contain improvements with respect to the mixed signal behaviour in high frequency applications since separate analog and digital grounds can be provided not only on chip and application board but also on the paddle of the package. Two separated paddles ideally provide a good ground transmission from die to application board to improve not only high frequency and thermal behaviour but also mixed signal performance. That is, it is possible to separately transfer digital and analog grounds from die to board.

Further, commonly used ground wire bonding techniques can be utilised on the separated paddles without deteriorating the mixed signal performance. Moreover, ground wire bonding reduces the overall number of I/O pins for the integrated circuit solution. With this in mind, the package size can be significantly reduced even with the same pitch of the I/O pins. That is, lowering the I/O pin number enables a design of smaller packages while keeping the same pin pitch necessary to avoid difficulties on board layout.

It is noted that the above described packaging technique is in particular suitable for mixed signal solutions beyond 5 GHz, in particular in the 5.2 GHz and 5.8 GHz frequency bands. By reducing cross talking, the operation speed can be increased.

While the invention has been described with respect to the physical embodiments constructed in accordance therewith, it will be apparent to those skilled in the art that various modifications, variations and improvements of the present invention may be made in the light of the above teachings and within the purview of the appended claims without departing from the spirit and intended scope of the invention. For instance, while the invention can be used with direct contact (paddle) package solutions such as QFN or MLF, it is to be noted that the invention is not limited to such techniques.

In addition, those areas in which it is believed that those of ordinary skill in the art are familiar, have not been described herein in order to not unnecessarily obscure the invention described herein. Accordingly, it is to be understood that the invention is not to be limited by the specific illustrative embodiments, but only by the scope of the appended claims.

What is claimed is:

1. A package for packaging a semiconductor die and providing electrical contacts to said packaged semiconductor die, comprising:
a first die attach paddle connectable to a first part of a bottom surface of the semiconductor die; and
a second die attach paddle connectable to a second part of the bottom surface of the semiconductor die;
wherein the first and second die attach paddles are each made of an electrically conductive material, and
wherein the first and second die attach paddles are electrically separated from each other.

2. The package of claim 1, further comprising a plurality of leads for, when electrically connected to the semiconductor die, providing said electrical contacts, said plurality of leads being held together thereby forming a lead frame.

3. The package of claim 2, wherein said first and second die attach paddles are fixed to said lead frame.

4. The package of claim 2, wherein at least one of said first and second die attach paddles is fixed to a paddle lead on a corner of said lead frame.

5. The package of claim 4, wherein said at least one die attach paddle is further fixed to a second paddle lead on another corner of said lead frame.

6. The package of claim 4, wherein said at least one die attach paddle is further fixed to at least one of said plurality of leads.

7. The package of claim 2, wherein at least one of said first and second die attach paddles has a three point connection to said lead frame.

8. The package of claim 2, wherein at least one of said first and second die attach paddles is fixed to said lead frame at multiple connection points, the number of connection points being greater than four.

9. The package of claim 1, further comprising a plurality of leads for, when electrically connected to the semiconductor die, providing said electrical contacts,
wherein at least one of said first and second die attach paddles is fixed to one of said plurality of leads.

10. The package of claim 9, wherein said plurality of leads are arranged in the package to substantially form a rectangle, and said one of said plurality of leads is located near the center of one side of said rectangle.

11. The package of claim 10, wherein said at least one die attach paddle is further fixed to a paddle lead on a corner of said rectangle.

12. The package of claim 9, wherein said plurality of leads are arranged in the package to substantially form a rectangle, and said one of said plurality of leads is located near a corner of said rectangle.

13. The package of claim 9, wherein said plurality of leads are held together thereby forming a lead frame, and said at least one die attach paddle is further fixed to at least one paddle lead on at least one corner of said lead frame.

14. The package of claim 9, wherein:
said at least one of said first and second die attach paddles is further fixed to another one of said plurality of leads;
said another one of said plurality of leads is located adjacent to said one of said plurality of leads; and
said one and said another one of said plurality of leads form a multiple common lead.

15. The package of claim 1, wherein the first and second die attach paddles are exposed on the bottom surface of the semiconductor device package.

16. The package of claim 1, wherein the first and second die attach paddles each have a size of about half of the area of the bottom surface of the semiconductor die.

17. The package of claim 16, wherein the first and second die attach paddles each have a substantially rectangular shape.

18. The package of claim 1, wherein:
the first and second die attach paddles have a first and second shape, respectively, in a plane parallel to the bottom surface of the semiconductor die;
the first shape is adapted to the shape of the first part of the bottom surface of the semiconductor die; and
the second shape is adapted to the shape of the second part of the bottom surface of the semiconductor die.

19. The package of claim 1, further comprising a plurality of leads for, when electrically connected to the semiconductor die, providing said electrical contacts,
wherein the first and second die attach paddles are electrically separated from each other by providing a spatial distance between the first and the second die attach paddles, and said spatial distance is greater than the width of one of said plurality of leads.

20. The package of claim 1, further comprising a plurality of leads for, when electrically connected to the semiconductor die, providing said electrical contacts,
wherein the first and second die attach paddles are electrically separated from each other by providing a spatial distance between the first and the second die attach paddles, and said spatial distance is substantially equal to the distance of two adjacent leads of said plurality.

21. A semiconductor device, comprising:
a first die attach paddle made of an electrically conductive material;
a second die attach paddle made of an electrically conductive material; and
at least one semiconductor die having a bottom surface attached to said first and second die attach paddles;
wherein the first and second die attach paddles are electrically separated from each other.

22. The semiconductor device of claim 21, wherein:
the semiconductor device comprises one semiconductor die;
the bottom surface of said one semiconductor die has a first part and a second part;
the first part of the bottom surface is attached to said first die attach paddle; and
the second part of the bottom surface is attached to said first die attach paddle.

23. The semiconductor device of claim 22, wherein the first and second parts of the bottom surface are electrically connected to the respective die attach paddles.

24. The semiconductor device of claim 23, wherein:
the semiconductor die carries a first circuitry and a second circuitry;
the first part of the bottom surface provides a ground contact of the first circuitry; and
the second part of the bottom surface provides a ground contact of the second circuitry.

25. The semiconductor device of claim 24, wherein the first circuitry is an analog circuitry for processing analog signals, and the second circuitry is a digital circuitry for processing digital signals.

26. The semiconductor device of claim 24, wherein the first and second die attach paddles are shaped corresponding to the shapes of the first and second parts of the bottom surface, respectively.

27. The semiconductor device of claim 23, wherein the first and second die attach paddles are exposed on the bottom surface of the semiconductor device package.

28. The semiconductor device of claim 21, wherein:
the semiconductor device comprises two semiconductor dies;
said bottom surface has a first part relating to the first semiconductor die and a second part relating to the second semiconductor die;
the first part of the bottom surface is attached to said first die attach paddle; and
the second part of the bottom surface is attached to said first die attach paddle.

29. The semiconductor device of claim 28, wherein the first and second parts of the bottom surface are electrically connected to the respective die attach paddles.

30. The semiconductor device of claim 29, wherein:
the first part of the bottom surface provides a ground contact of the first semiconductor die; and
the second part of the bottom surface provides a ground contact of the second semiconductor die.

31. The semiconductor device of claim 30, wherein the first semiconductor die is arranged for processing analog signals, and the second semiconductor die is arranged for processing digital signals.

32. The semiconductor device of claim 30, wherein the first and second die attach paddles are shaped corresponding to the shapes of the first and second parts of the bottom surface, respectively.

33. The semiconductor device of claim 29, wherein the first and second die attach paddles are exposed on the bottom surface of the semiconductor device package.

34. The semiconductor device of claim 21, wherein the first and second die attach paddles are connected to provide ground contacts for analog and digital signals, respectively.

35. The semiconductor device of claim 21, wherein the at least one semiconductor die carries a first circuitry and a second circuitry;
the bottom surface provides a first contact relating to the first circuitry and a second contact relating to the second circuitry;
the first and second die attach paddles are attached to the first and second contacts, respectively; and
the first and second die attach paddles correspond in shape to the respective first and second contacts.

36. The semiconductor device of claim 21, wherein said at least one semiconductor die comprises integrated circuits for processing analog and digital signals having frequencies of greater than 5 GHz.

37. The semiconductor device of claim 21, further comprising a plurality of leads for, when electrically connected to the at least one semiconductor die, providing electrical contacts to the at least one semiconductor die, said plurality of leads being held together thereby forming a lead frame.

38. The semiconductor device of claim 37, wherein said first and second die attach paddles are fixed to said lead frame.

39. The semiconductor device of claim 37, wherein at least one of said first and second die attach paddles is fixed to a paddle lead on a corner of said lead frame.

40. The semiconductor device of claim 39, wherein said at least one die attach paddle is further fixed to a second paddle lead on another corner of said lead frame.

41. The semiconductor device of claim 39, wherein said at least one die attach paddle is further fixed to at least one of said plurality of leads.

42. The semiconductor device of claim 37, wherein at least one of said first and second die attach paddles has a three point connection to said lead frame.

43. The semiconductor device of claim 37, wherein at least one of said first and second die attach paddles is fixed to said lead frame at multiple connection points, the number of connection points being greater than four.

44. The semiconductor device of claim 21, further comprising a plurality of leads for, when electrically connected to the at least one semiconductor die, providing electrical contacts to the at least one semiconductor die,
wherein at least one of said first and second die attach paddles is fixed to one of said plurality of leads.

45. The semiconductor device of claim 44, wherein said plurality of leads are arranged in the package to substantially form a rectangle, and said one of said plurality of leads is located near the center of one side of said rectangle.

46. The semiconductor device of claim 44, wherein:
said at least one of said first and second die attach paddles is further fixed to another one of said plurality of leads;
said another one of said plurality of leads is located adjacent to said one of said plurality of leads; and
said one and said another one of said plurality of leads form a multiple common lead.

47. The semiconductor device of claim 21, wherein the first and second die attach paddles each have a size of about half of the area of the bottom surface of the at least one semiconductor die.

48. The semiconductor device of claim 47, wherein the first and second die attach paddles each have a substantially rectangular shape.

49. The semiconductor device of claim 21, further comprising a plurality of leads for, when electrically connected to the at least one semiconductor die, providing electrical contacts to the at least one semiconductor die,
wherein the first and second die attach paddles are electrically separated from each other by providing a spatial distance between the first and the second die attach paddles, and said spatial distance is greater than the width of one of said plurality of leads.

50. The semiconductor device of claim 21, further comprising a plurality of leads for, when electrically connected to the at least one semiconductor die, providing electrical contacts to the at least one semiconductor die,
wherein the first and second die attach paddles are electrically separated from each other by providing a spatial distance between the first and the second die attach paddles, and said spatial distance is substantially equal to the distance of two adjacent leads of said plurality.

51. A method of fabricating a package for packaging a semiconductor die and providing electrical contacts to said packaged semiconductor die, the method comprising:
providing a first die attach paddle made of an electrically conductive material;
providing a second die attach paddle made of an electrically conductive material; and
placing the first and second die attach paddles so that the bottom surface of said semiconductor die can be attached to the first and second die attach paddles, and the first and second die attach paddles are electrically separated from each other.

52. A method of packaging a semiconductor die, the method comprising:
providing a package having a first die attach paddle and a second die attach paddle made of an electrically conductive material and being electrically separated from each other;
providing the semiconductor die; and
attaching the bottom surface of the semiconductor die to the first and second die attach paddles.
